(19) United States
(12) Patent Application Publication
(10) Pub. No.: US 2008/0231289 A1
(43) Pub. Date: Sep. 25, 2008

(54) CLAMPING APPARATUS AND A SYSTEM AND METHOD FOR DETECTING DEFECTS IN ELECTRICAL WIRING

(75) Inventors: Meena Ganesh, Clifton Park, NY (US); Selaka Bandara Bulumulla, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 11/687,870

(22) Filed: Mar. 19, 2007

(51) Int. Cl. G01R 31/02

(52) U.S. Cl. 324/539

(57) ABSTRACT

A wire diagnostic clamp including a clamp body configured to receive multiple electrical wires is provided. The wire diagnostic clamp also includes a sensor disposed within the clamp body and being configured to detect a defect in the multiple electrical wires. The wire diagnostic clamp further includes a mounting component configured to mount the wire diagnostic clamp to a substrate.

### STATEMENT REGARDING FEDERALLY SPONSORED RESEARCH & DEVELOPMENT

This invention was made with Government support under contract number N00421-05-D-0116 awarded by NAVAIR. The Government has certain rights in the invention.

### BACKGROUND

The invention relates generally to diagnostics of wiring systems and more specifically, to diagnostics of aircraft wiring systems.

Insulation failure in wiring systems in aircraft industry is a critical safety concern since discharges from electrical wires may lead to on-board fires or other hazardous conditions. Hence, maintenance of the wiring system is an important factor in maintenance of the aircraft. However, wiring in a typical aircraft may extend in length up to several kilometers, hindering manual inspection for defects.

Some commonly used diagnostic systems include time domain reflectometry and frequency domain reflectometry. The techniques include a pulsed signal that may be applied to the wiring system. A reflected signal is analyzed for anomalies in the wiring. However, these techniques require the wires to be disconnected from a harness.

Insulation failure has been primarily attributed to aging of the wires leading to cracks in the insulation. Further, improper installation and handling may also lead to defects in insulation. Initial degradation in the insulation may start with microscopic cracks that result in small electrical discharges. The discharges may further carbonize the insulation leading to a full arc discharge. The small electrical discharges cannot be detected by the existing diagnostic systems. In order to resolve the issue, multiple sensors are added that may acquire electromagnetic signals due to the electrical discharges. However, addition of sensors to the wiring system increases weight of the aircraft leading to an increased maintenance time and cost.

Hence, there is a need for an improved diagnostic system for the aircraft wiring system that addresses the aforementioned issues, including continuous monitoring and diagnostics during the operation of the aircraft.

### BRIEF DESCRIPTION

In accordance with an aspect of the invention, a wire diagnostic clamp including a clamp body configured to receive a plurality of electrical wires is provided. The wire diagnostic clamp includes a sensor disposed within the clamp body and being configured to detect a defect in the plurality of electrical wires. The wire diagnostic clamp further includes a mounting component configured to mount the wire diagnostic clamp to a substrate.

In accordance with another aspect of the invention, a system for detecting defects in electrical wiring is provided. The system includes a wire diagnostic clamp having a clamp body and being configured to receive a plurality of electrical wires. The system also includes a sensor disposed within the wire diagnostic clamp body and being configured to detect a defect in the multiple electrical wires. The system further includes a mounting component configured to mount the wire diagnostic clamp to a substrate and a connector configured to provide an electrical connection between the sensor and a data acquisition system.

In accordance with another aspect of the invention, a method for detecting defects in electrical wiring is provided. The method includes disposing a sensor within a clamp body of the wire diagnostic clamp and around the multiple electrical wires within the wire diagnostic clamp, providing an electrical connection between the sensor and a data acquisition system via a connector, and mounting the wire diagnostic clamp body to a substrate.

### DRAWINGS

These and other features, aspects, and advantages of the present invention will become better understood when the following detailed description is read with reference to the accompanying drawings in which like characters represent like parts throughout the drawings, wherein:

FIG. 1 is a perspective view of a wire diagnostic clamp including a sensor in accordance with an embodiment of the invention;

FIG. 2 is a front side view of the wire diagnostic clamp of FIG. 1;

FIG. 3 is a cross-sectional view of the wire diagnostic clamp taken along line 3-3 of FIG. 2;

FIG. 4 is a block diagram representation of a wire harness in an aircraft system employing the wire diagnostic clamp in FIG. 1 for detecting defects in electrical wiring in accordance with an embodiment of the invention; and

FIG. 5 is a flow chart representing steps involved in detecting defects in electrical wiring in accordance with an embodiment of the invention.

### DETAILED DESCRIPTION

As discussed in detail below, embodiments of the invention include a clamping apparatus, a system and a method for detecting defects in electrical wiring. The term ‘defects’ as used herein, refers to electrical discharges in the electrical wiring due to reasons such as, but not limited to, a failure in insulation in the electrical wiring due to aging of the electrical wiring, improper installation, improper handling, and external factors such as temperature and humidity. The clamping apparatus may be used in conjunction with a passive detection technique of General Electric, namely, Smart Wire diagnostic systems (SWDS), to detect defects in the electrical wiring. Further details of the SWDS may be obtained in U.S. Pat. No. 6,930,610 B2.

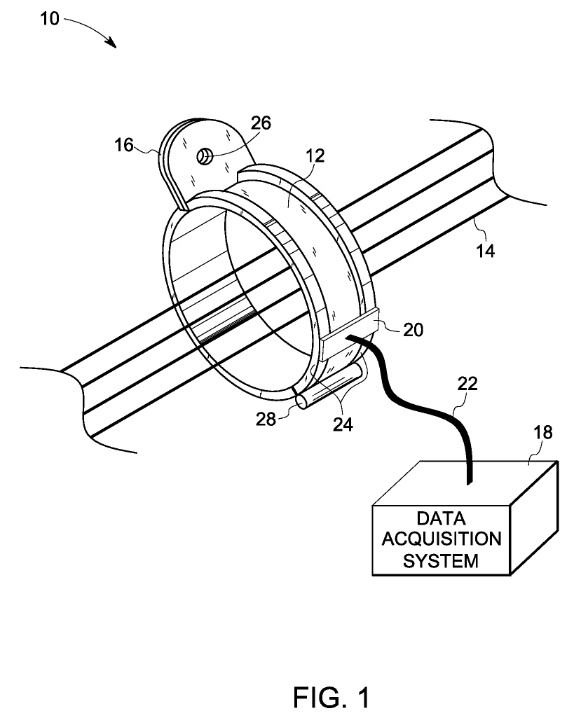

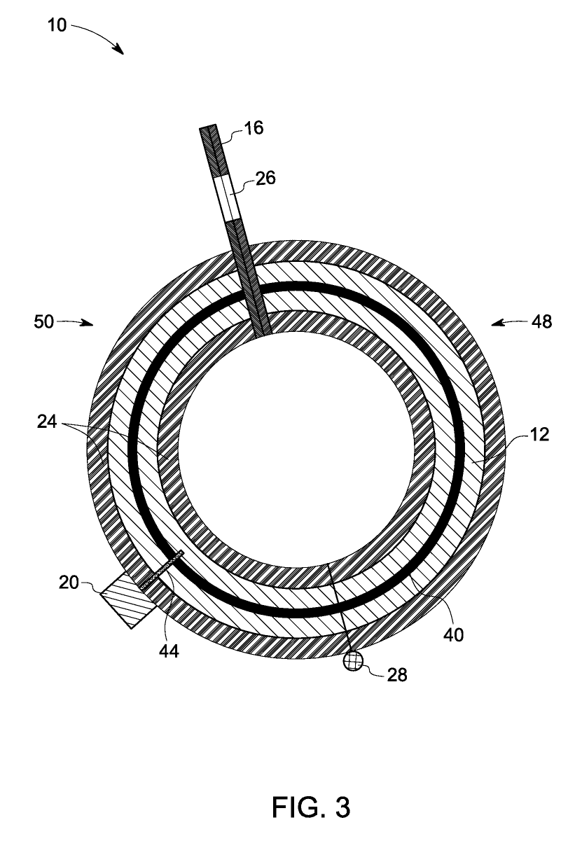

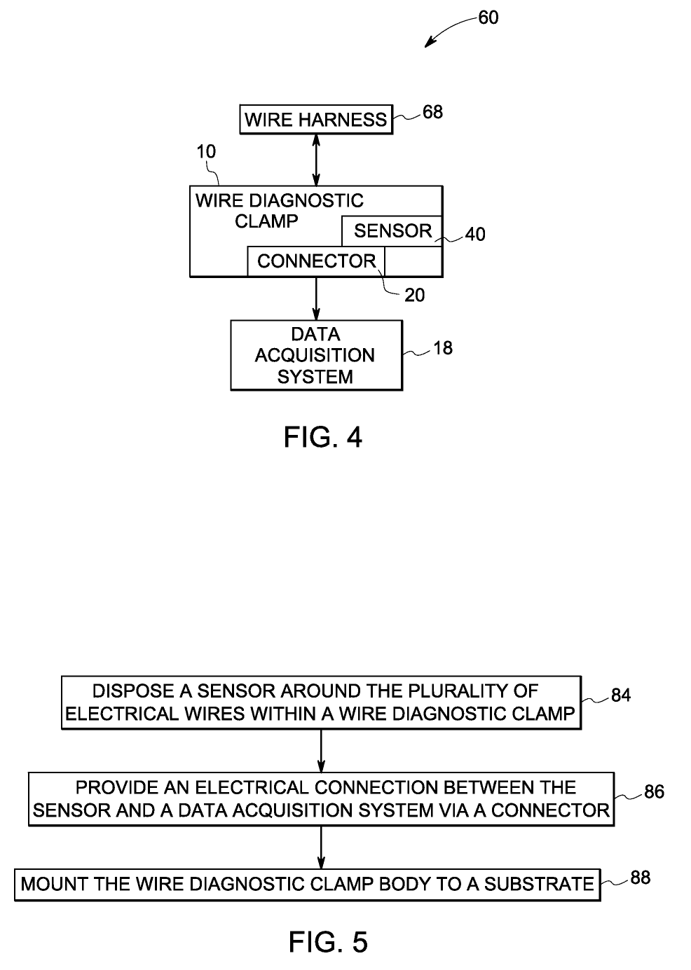

Turning to FIGS. 1-3, there is shown a wire diagnostic clamp 10. The wire diagnostic clamp 10 includes a clamp body 12 that is configured to receive multiple electrical wires 14. In a particular embodiment, the electrical wires 14 may be bundled together via a wire harness. In another embodiment, the electrical wires 14 may not be bundled together. The wire diagnostic clamp 10 also includes a sensor 40 (FIG. 3) disposed within the clamp body 12. The sensor enables detection of defects in the electrical wires 14 by acquiring an electromagnetic signal from an electrical discharge due to the defect. A mounting component 16 may be attached to the clamp body 12 to mount the wire diagnostic clamp 10 onto a substrate. In a particular embodiment, the substrate may be an aircraft frame 68 (FIG. 4). The clamp body 12 may include a metal or a plastic. In a particular embodiment, the clamp body 12 may be aluminum or steel. Mounting component 16 may include holes 26 for use in attaching the wire diagnostic clamp 10 to the substrate. Further, the wire diagnostic clamp 10 may be coupled to a data acquisition system 18 via a connector 20 coupled to the sensor 40 within the wire diagnostic clamp 10. A lead 22 provides electrical connection to the data acquisition system 18. The wire diagnostic clamp 10 also includes a rubber cushion 24 over the clamp body 12 that prevents direct contact between the electrical wires 14 and the metallic portion of the clamp body 12. A hinge 28 enables opening of the wire diagnostic clamp 10 to install the sensor 40 and the wires 14.

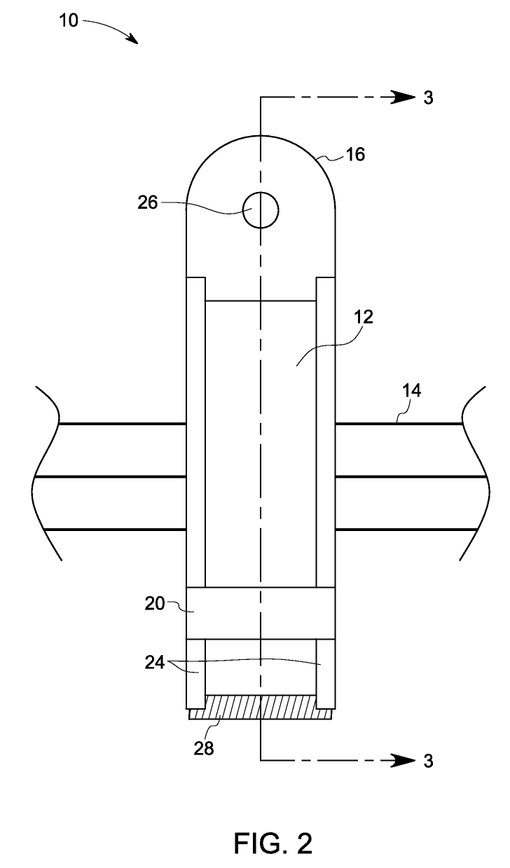

FIG. 2 is a front side view of the wire diagnostic clamp 10 in FIG. 1. The mounting component 16 including holes 26 is attached to the clamp body 12. The rubber cushion 24 over the clamp body 12 prevents electrical contact between the wires 14 and the clamp body 12. The connector 20 enables electrical connection to the data acquisition system 18 (FIG. 1) and the hinge 28 enables opening of the clamp body 12.

FIG. 3 is a cross-sectional view of the wire diagnostic clamp 10 in FIG. 1 along line 3-3 in FIG. 2. A sensor 40 is disposed within a clamp body 12. In a particular embodiment, the sensor 40 is a flexible and a lightweight coil sensor. Further details of the sensor may be obtained in U.S. Pat. No. 7,002,356 B2. The thickness of the sensor 40 may be in a range between about 5 mils and about 10 mils, wherein 1 mil=25.4 micrometer. The weight of the sensor 40 may range between about 0.2 gms to about 1 gm. The sensor 40 is attached to a center conductor 42 of the connector 20 as referenced in FIG. 1. The connector 20 provides an electrical connection between the sensor 40 and a data acquisition system 18 as referenced in FIG. 1. In a non-limiting example, the connector 20 is a coaxial radiofrequency connector such as a subminiature version A (SMA) connector or a Bayonet Neill-Concelman connector (BNC). A hinge 28 enables opening of the wire diagnostic clamp 10 into two halves 48 and 50.

A bundle of electrical wires 14 are installed within the wire diagnostic clamp 10. In a particular embodiment, the sensor 40 is disposed around the bundle of electrical wires 14 within the clamp body 12. In a particular embodiment, the wire diagnostic clamp 10 also includes a rubber cushion 24 to avoid direct contact between the electrical wires 14 and the clamp body 12 that is metallic. The rubber cushion 24 loops around the bundle of electrical wires 14.

FIG. 4 is a block diagram representation of a system 60 for detecting defects in electrical wiring in an aircraft. The system 60 includes at least one wire diagnostic clamp 10 with a sensor 40 disposed within the wire diagnostic clamp 10. In a particular embodiment, the sensor 40 is a flexible coil sensor. In another embodiment, thickness of the sensor includes a range between about 5 mils and about 10 mils. The wire diagnostic clamp 10 is mounted to a wire harness 68 in an aircraft frame. Further, a connector 20 within the wire diagnostic clamp 10 provides electrical connection between the sensor 40 and a data acquisition system 18. The data acquisition system 18 analyzes electrical data from the sensor 40 to detect a defect in the electrical wiring in the aircraft.

There are a large number of electrical wires 14 carrying electrical power and communication signals for efficient operation of an aircraft system. The entire electrical wiring installation is hidden behind a wire harness 68 in an aircraft frame. Multiple wire diagnostic clamps 10 may be employed to enable organizing wiring and to avoid cluttering of the electrical wires 14. In a particular embodiment, the wire diagnostic clamps 10 are installed at a space of about 6 to about 8 inches along a length of a bundle of the electrical wires 14. The wire diagnostic clamps are lightweight and may replace existing clamps that are used in wire harnesses eliminating additional load on the aircraft system.

FIG. 5 is a flow chart representing exemplary steps in a method for detecting defects in electrical wiring. The method includes disposing a sensor within a wire diagnostic clamp body of a wire diagnostic clamp and around multiple electrical wires in step 84. In a particular embodiment, the method also includes inserting a wire diagnostic clamp around existing wires. In another embodiment, the inserting includes opening the wire diagnostic clamp via a hinge. The sensor is electrically connected to a data acquisition system via a connector in step 86. In a particular embodiment, the sensor is electrically connected via a center conductor of the connector. Further, the wired diagnostic clamp body is mounted to a substrate in step 88. In a particular embodiment, the wire diagnostic clamp body is mounted to the substrate.

The various embodiments of a clamping apparatus and a system for detecting defects in an electrical wiring system and a method for the same described above thus provide a way to achieve convenient, efficient and accurate detection of defects. These techniques and systems also allow for highly efficient aircraft systems due to improved electrical wiring fault detection.

Of course, it is to be understood that not necessarily all such objects or advantages described above may be achieved in accordance with any particular embodiment. Thus, for example, those skilled in the art will recognize that the systems and techniques described herein may be embodied or carried out in a manner that achieves or optimizes one advantage or group of advantages as taught herein without necessarily achieving other objects or advantages as may be taught or suggested herein.

Furthermore, the skilled artisan will recognize the interchangeability of various features from different embodiments. For example, the use of a BNC connector with respect to one embodiment can be adapted for use with an aluminum wire diagnostic clamp described with respect to another. Similarly, the various features described, as well as other known equivalents for each feature, can be mixed and matched by one of ordinary skill in this art to construct additional systems and techniques in accordance with principles of this disclosure.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A wire diagnostic clamp, comprising:
a clamp body configured to receive a plurality of electrical wires;
a sensor disposed within the clamp body and being configured to detect a defect in the plurality of electrical wires; and
a mounting component configured to mount the wire diagnostic clamp to a substrate.

2. The wire diagnostic clamp of claim 1, wherein the sensor comprises a flexible coil sensor.

3. The wire diagnostic clamp of claim 1, wherein a thickness of the sensor comprises a range between about 5 mils and about 10 mils.

4. The wire diagnostic clamp of claim 1, wherein the sensor is disposed around the plurality of electrical wires within the clamp body.

5. The wire diagnostic clamp of claim 1, wherein the clamp body comprises a metal or a plastic.

6. The wire diagnostic clamp of claim 5, wherein the metal comprises aluminum or steel.

7. The wire diagnostic clamp of claim 1, comprising a connector configured to provide electrical connection to the sensor.

8. The wire diagnostic clamp of claim 1, wherein the defect comprises an electrical discharge in the plurality of wires.

9. The wire diagnostic clamp of claim 1, comprising a hinge disposed on the clamp body.

10. A system for detecting defects in electrical wiring, comprising:
a wire diagnostic clamp having a clamp body and being configured to receive a plurality of electrical wires;
a sensor disposed within the clamp body and being configured to detect a defect in the plurality of electrical wires;
a mounting component configured to mount the wire diagnostic clamp to a substrate, and
a connector configured to provide an electrical connection between the sensor and a data acquisition system.

11. The system of claim 10, wherein the sensor comprises a flexible coil sensor.

12. The system of claim 10, wherein a thickness of the sensor comprises a range between about 5 mils and about 10 mils.

13. The system of claim 10, wherein the sensor is disposed around the plurality of electrical wires within the clamp body.

14. The system of claim 10, wherein the clamp body comprises a metal or a plastic.

15. The system of claim 14, wherein the metal comprises aluminum or steel.

16. The system of claim 10, wherein the defect comprises an electrical discharge in the plurality of wires.

17. The system of claim 10, further comprising a hinge disposed on the clamp body.

18. A method for detecting defects in electrical wiring, comprising:
disposing a sensor within a wire diagnostic clamp body of the wire diagnostic clamp and around a plurality of electrical wires within the wire diagnostic clamp;
providing an electrical connection between the sensor and a data acquisition system via a connector; and
mounting the wire diagnostic clamp body to a substrate.

19. The method of claim 18, wherein said providing an electrical connection comprises coupling the sensor with a center conductor of the connector.

20. The method of claim 18, comprising monitoring and analyzing an electrical signal from the sensor via the data acquisition system.

21. The method of claim 18, further comprising inserting the wire diagnostic clamp around the plurality of electrical wires.

22. The method of claim 21, wherein said inserting the wire diagnostic clamp comprises opening the wire diagnostic clamp via a hinge.
